(19) United States
(12) Patent Application Publication
(10) Pub. No.: US 2026/0126687 A1
(43) Pub. Date: May 7, 2026

(54) ELECTRONIC DEVICE

(71) Applicants: Innolux Corporation, Miaoli County (TW); CARUX TECHNOLOGY PTE. LTD., SINGAPORE (SG)

(72) Inventors: Chen-Lin Yeh, Miaoli County (TW); Chia-Hsien Hsieh, Miaoli County (TW); Hong-Sheng Hsieh, Miaoli County (TW); Li-Wei Sung, Tainan (TW)

(73) Assignees: Innolux Corporation, Miaoli County (TW); CARUX TECHNOLOGY PTE. LTD., SINGAPORE (SG)

(21) Appl. No.: 19/379,748

(22) Filed: Nov. 5, 2025

(30) Foreign Application Priority Data
Nov. 5, 2024 (TW) 113142231

(51) Int. Cl. G02F 1/1335; H10H 29/85; H10K 59/38

(52) U.S. Cl. CPC G02F 1/133512; G02F 1/133514; H10H 29/8517; H10K 59/38

(57) ABSTRACT

An electronic device including a first substrate, a second substrate, a display medium layer, a color filter layer, and a viewing-angle barrier layer is provided. The second substrate is disposed opposite to the first substrate and includes a first surface facing the first substrate and a second surface facing away from the first substrate. The display medium layer is disposed between the first substrate and the second substrate. The color filter layer is disposed between the display medium layer and the second substrate. The viewing-angle barrier layer contacts one of the first surface and the second surface. In a normal direction of the first surface, a thickness of the second substrate is less than a thickness of the first substrate.

### CROSS-REFERENCE TO RELATED APPLICATION

This application claims the priority benefit of Taiwan application serial no. 113142231, filed on Nov. 5, 2024. The entirety of the above-mentioned patent application is hereby incorporated by reference herein and made a part of this specification.

### BACKGROUND

### Technical Field

This disclosure relates to an electronic device, and particularly relates to a display device having a viewing-angle barrier layer.

### Description of Related Art

Electronic devices including display panels, such as tablet computers, notebook computers, smartphones, monitors, and televisions, have become indispensable necessities in modern society. With the booming development of portable electronic products, consumers have high expectations for the quality, functionality, or price of these products.

The functions of automotive audio-visual systems are becoming increasingly rich. Based on safety considerations, the display system on the front passenger seat needs to be equipped with a privacy protection function to reduce distraction to the driver during driving conditions and a sharing display function to share information with the driver during non-driving conditions. In recent years, dual-view display or multi-view display modules have been widely applied in automotive audio-visual systems. Such dual-view display or multi-view display modules commonly employ a viewing-angle barrier layer to enable the display to simultaneously present two or more different screens or viewing-angles.

Generally speaking, a more cost-effective approach to achieving dual-view or multi-view display technology involves attaching a designed viewing-angle barrier layer to the outside of the color filter substrate of the display. However, this method performs poorly in terms of resolution for dual-view or multi-view displays. In addition, the use of an externally attached viewing-angle barrier layer also makes it more difficult to achieve high-precision alignment accuracy, which in turn affects the yield and production output of the manufacturing process.

Based on the above, developing structural designs that may further improve the display performance of an electronic device remains one of the subjects that the industry is currently dedicated to researching.

### SUMMARY

According to some embodiments of the disclosure, an electronic device is provided including a first substrate, a second substrate, a display medium layer, a color filter layer, and a viewing-angle barrier layer. The second substrate is disposed opposite to the first substrate and includes a first surface facing the first substrate and a second surface facing away from the first substrate. The display medium layer is disposed between the first substrate and the second substrate. The color filter layer is disposed between the display medium layer and the second substrate. The viewing-angle barrier layer contacts one of the first surface and the second surface. In a normal direction of the first surface, a thickness of the second substrate is less than a thickness of the first substrate.

In order to make the above-mentioned features and advantages of the disclosure clearer and easier to understand, the following embodiments are given and described in details with accompanying drawings as follows.

### BRIEF DESCRIPTION OF THE DRAWINGS

FIG. 1 shows a schematic structural diagram of an electronic device according to some embodiments of the disclosure.

FIG. 2 shows a schematic structural diagram of an electronic device according to some embodiments of the disclosure.

FIG. 3 shows a schematic structural diagram of an electronic device according to some embodiments of the disclosure.

FIG. 4 shows a schematic diagram of viewing-angle determination according to some embodiments of the disclosure.

FIG. 5 shows a light pattern distribution diagram illustrating the relationship between transmittance (opening ratio) and viewing-angle (0g) according to some embodiments of the disclosure.

FIG. 6 shows a schematic structural diagram of some components of an electronic device including design parameters according to some embodiments of the disclosure.

FIG. 7A to FIG. 7C show different types of light pattern diagrams according to some embodiments of the disclosure.

FIG. 8 shows a schematic structural diagram of some components of an electronic device including design parameters according to some embodiments of the disclosure.

FIG. 9 shows corresponding light pattern diagrams obtained by using different viewing-angle barrier layers according to some embodiments of the disclosure.

FIG. 10 shows a schematic structural diagram of some components in an electronic device according to some embodiments of the disclosure.

FIG. 11 shows a schematic structural diagram of some components in an electronic device according to some embodiments of the disclosure.

FIG. 12A to FIG. 12C show top view schematic structural diagrams of viewing-angle barrier layers of different aspects and schematic diagrams of the displayed screens according to some embodiments of the disclosure.

### DESCRIPTION OF THE EMBODIMENTS

An electronic device of an embodiment of the disclosure will be described in detail below. It should be appreciated that the following description provides many different embodiments for implementing various aspects of some embodiments of the disclosure. The specific elements and arrangements described below briefly and clearly describe some embodiments of the disclosure. Of course, these are examples and not limitations of the disclosure. Furthermore, similar and/or corresponding reference numerals may be used in different embodiments to designate similar and/or corresponding elements in order to clearly describe the disclosure. However, the use of these similar and/or corresponding reference numerals is for simplicity and clarity in describing some embodiments of the disclosure and does not imply any relationship between the different embodiments and/or structures discussed.

It should be understood that, relative terms, such as “lower” or “bottom” or “higher” or “top,” may be used in the embodiments to describe the relative relationship of one element of the drawings to another element. It will be understood that if the device in the figures were turned upside down, elements described on the “lower” side would become elements described on the “higher” side. The embodiments of the disclosure may be understood together with the drawings, and the drawings of the disclosure are also regarded as a part of the disclosure description. It should be understood that the drawings of the disclosure are not drawn to scale, and in fact, the dimensions of elements may be arbitrarily enlarged or reduced in order to clearly represent the features of the disclosure.

Moreover, when it is mentioned that a first material layer is located on or over a second material layer, the first material layer and the second material layer may be in direct contact or the first material layer and the second material layer may not be in direct contact. That is, one or more other material layers may be spaced between the first material layer and the second material layer. However, if the first material layer is directly located on the second material layer, it means that the first material layer and the second material layer are in direct contact.

Moreover, it should be noted that, the ordinal numbers used in the specification and claims, such as “first”, “second”, etc., are used to modify an element. They do not themselves imply and represent that the element(s) have any previous ordinal number, and also do not represent the order of one element and another element, or the order of manufacturing methods. The use of these ordinal numbers is to clearly distinguish an element with a certain name from another element with the same name. The same terms may be omitted in the claims and the specification. For example, the first element in the specification may be the second element in the claims.

In some embodiments of the disclosure, terms such as “connection”, “interconnection”, etc., regarding bonding and connection, unless specifically defined, may mean that two structures are in direct contact, or that two structures are not in direct contact and there are other structures located between these two structures. Moreover, the terms of bonding and connection may also include the case where both structures are movable or both structures are fixed. In addition, the terms “electrically connected” or “electrically coupled” include any direct and indirect electrical connection means.

In the specification, the terms “about” and “substantially” generally mean within 10%, or within 5%, or within 3%, or within 2%, or within 1%, or within 0.5% of a given value or range. Quantities given herein are approximate quantities, that is, in the absence of a specific description of “about” and “substantially”, the meanings of “about” and “substantially” may still be implied. The phrase “a range between a first numerical value and a second numerical value” means that the range includes the first numerical value, the second numerical value, and other numerical values in between. In addition, there may be a certain error in any two numerical values or directions for comparison. If the first numerical value is equal to the second numerical value, it implies that there may be an error of about 10% between the first numerical value and the second numerical value. If the first direction is perpendicular to the second direction, the angle between the first direction and the second direction may be between 80 degrees and 100 degrees. If the first direction is parallel to the second direction, the angle between the first direction and the second direction may be between 0 degrees and 10 degrees.

According to embodiments of the disclosure, a scanning electron microscope (SEM), an optical microscope (OM), a thin film thickness profiler (α-step), an ellipsometer, or other suitable methods may be used to measure the width, thickness or height of each component, and the spacing or distance between components. In detail, according to some embodiments, a scanning electron microscope may be used to obtain cross-sectional structure images including the components to be measured, and measure the width, thickness or height of each component, and the spacing or distance between components.

It should be noted that in the following embodiments, the features in several different embodiments may be replaced, recombined, and mixed to complete other embodiments without departing from the spirit of the disclosure. As long as the features between the embodiments do not violate the spirit of the disclosure or conflict with each other, they may be mixed and used arbitrarily.

Unless otherwise defined, all terms (including technical and scientific terms) used herein have the same meaning as commonly understood by those skilled in the art to which the disclosure belongs. It should be understood that, these terms, such as those defined in commonly used dictionaries, should be interpreted as having meaning consistent with the relevant technique and the background or context of the disclosure, and should not be interpreted in an idealized or excessively formal manner, unless specifically defined in an embodiment of the disclosure.

According to embodiments of the disclosure, an electronic device including a viewing-angle barrier layer is provided. The viewing-angle barrier layer may be disposed within the color filter substrate (in-cell) or on the thinned color filter substrate (on-cell), and fabricated by a photolithography process to improve the alignment accuracy of the viewing-angle barrier layer, thereby improving the process yield and performance of the electronic device.

According to embodiments of the disclosure, the electronic device may be applied to a display device, a light-emitting device, a backlight device, a touch device, a sensing device, a wearable device, an automotive device, or a tiling device, but the disclosure is not limited thereto. The electronic device may be a bendable or flexible electronic device. The display device may be a non-self-luminous type display device or a self-luminous type display device. The sensing device may be a sensing device sensing capacitance, light, heat, or ultrasound, but the disclosure is not limited thereto. Furthermore, the electronic device may include a liquid crystal, a quantum dot (QD), a fluorescence, a phosphor, other suitable materials, or a combination thereof. The electronic device may include an electronic element, and the electronic element may include a passive element and an active element, such as a capacitor, a resistor, an inductor, a diode, a transistor, and so on. The diode may include a light-emitting diode or a photodiode. The light-emitting diode may include, for example, an organic light-emitting diode (OLED), a mini LED, a micro LED, or a quantum dot LED, but the disclosure is not limited thereto. According to some embodiments, the electronic device may include a panel and/or a backlight module, and the panel may include, for example, a liquid crystal panel or other self-luminous panels, but the disclosure is not limited thereto. The tiling device may be, for example, a display tiling device, but the disclosure is not limited thereto. It should be understood that the electronic device may be any combination of the above, but the disclosure is not limited thereto.

Referring to FIG. 1, FIG. 1 shows a schematic structural diagram of an electronic device 10 according to some embodiments of the disclosure. It should be noted that the drawing only schematically illustrates the stacked structure of the electronic device 10. According to some embodiments, additional features may be added to the electronic device 10 described below. According to some embodiments, the electronic device 10 may be an automotive display module, but the disclosure is not limited thereto.

As shown in FIG. 1, the electronic device 10 may include a first substrate 100, a second substrate 200, a display medium layer 300, a color filter layer 306, and a viewing-angle barrier layer 400.

The first substrate 100 may serve as a driving substrate (or array substrate). In detail, according to some embodiments, the electronic device 10 may further include a driving circuit layer 304 disposed on the first substrate 100. According to some embodiments, the driving circuit layer 304 may include an active driver circuit, such as one that includes a thin-film transistor. According to some embodiments, the first substrate 100 may include a flexible substrate, a rigid substrate, or a combination thereof, but the disclosure is not limited thereto. Furthermore, the first substrate 100 may be a transparent substrate. According to some embodiments, the material of the first substrate 100 may include glass, quartz, sapphire, ceramic, polyimide (PI), polycarbonate (PC), polyethylene terephthalate (PET), polypropylene (PP), other suitable materials, or a combination thereof, but the disclosure is not limited thereto.

The second substrate 200 is disposed opposite to the first substrate 100, and includes a first surface 200a facing the first substrate 100 and a second surface 200b facing away from the first substrate 100. In other words, the second substrate 200 may have a first surface 200a adjacent to the first substrate 100 and a second surface 200b away from the first substrate 100. The second substrate 200 may serve as a color filter substrate. According to some embodiments, the second substrate 200 may include a flexible substrate, a rigid substrate, or a combination thereof, but the disclosure is not limited thereto. Furthermore, the second substrate 200 may be a transparent substrate. According to some embodiments, the material of the second substrate 200 may include glass, quartz, sapphire, ceramic, polyimide (PI), polycarbonate (PC), polyethylene terephthalate (PET), polypropylene (PP), other suitable materials, or a combination thereof, but the disclosure is not limited thereto.

Furthermore, in the normal direction (Z direction) of the first surface 200a of the second substrate 200, a thickness T200 of the second substrate 200 is less than a thickness T100 of the first substrate 100. It is worth noting that the configuration may improve the alignment resolution of the viewing-angle barrier layer 400, for example, to the micrometer (μm) level, thereby improving the alignment accuracy of the viewing-angle barrier layer 400 and enhancing the process yield and performance of the electronic device.

The display medium layer 300 may be disposed between the first substrate 100 and the second substrate 200. According to some embodiments, the display medium layer 300 may include a liquid crystal, an organic light-emitting diode (OLED), a micro LED, other suitable display medium, or a combination thereof, but the disclosure is not limited thereto. According to some embodiments, the electronic device 10 may be a non-self-luminous type display device or a self-luminous type display device.

According to some embodiments, the electronic device 10 may further include an alignment layer 302A and an alignment layer 302B disposed on both sides of the display medium layer 300. The alignment layer 302A may be conformably disposed on the driving circuit layer 304, and the alignment layer 302B may be conformably disposed on the color filter layer 306, but the disclosure is not limited thereto. The alignment layer 302A and the alignment layer 302B may assist in controlling the material properties (for example, dielectric characteristics or alignment direction, etc.) in the display medium layer 300, thereby controlling the display characteristics of the display unit layer DU of the electronic device 10. According to some embodiments, the material of the alignment layer 302A and the alignment layer 302B may include organic material, inorganic material, or a combination thereof. For example, the organic material may include polyimide (PI), poly(vinyl cinnamate) (PVCN), polymethylmethacrylate (PMMA), other photoreactive polymer materials, or a combination thereof, but the disclosure is not limited thereto. The inorganic material may include, for example, silicon dioxide (SiO₂), silicon carbide (SiC), glass, silicon nitride (Si₃N₄), aluminum oxide (Al₂O₃), cerium oxide (CeO₂), other inorganic materials having alignment function, or a combination thereof, but the disclosure is not limited thereto.

Furthermore, the color filter layer 306 may be disposed between the display medium layer 300 and the second substrate 200. As mentioned above, the second substrate 200 may serve as a color filter substrate. In detail, the color filter layer 306 may be disposed on the second substrate 200, the driving circuit layer 304 may be disposed on the first substrate 100, the second substrate 200 and the color filter layer 306 thereon may be paired with the first substrate 100 and the driving circuit layer 304 thereon, and the display medium layer 300 may be sandwiched between the color filter layer 306 and the driving circuit layer 304. The color filter layer 306 may filter or adjust the optical properties of light rays transmitting through it, for example, allowing light rays of specific wavelength ranges to pass through. According to some embodiments, the upper surface of the color filter layer 306 may be viewed as the starting position of display light. According to some embodiments, the color filter layer 306 may include a blue filter layer, a green filter layer, and a red filter layer, and the blue filter layer, the green filter layer, and the red filter layer may be arranged in a specific manner, but the disclosure is not limited thereto. According to some embodiments, the material of the color filter layer 306 may include color photoresist, and the material of the color photoresist may include, for example, polymer material and pigments and photosensitive materials dispersed therein, but the disclosure is not limited thereto. According to some embodiments, the polymer material may include epoxy resin, acrylic resin such as polymethylmetacrylate (PMMA), benzocyclobutene (BCB), other suitable materials, or a combination thereof, but the disclosure is not limited thereto. In some embodiments, the electronic device may not be provided with the color filter layer 306 or the surrounding light-shielding layer 308 according to requirements, but the disclosure is not limited thereto.

Furthermore, according to some embodiments, the electronic device 10 may further include a light-shielding layer 308 disposed around the color filter layer 306, and the light-shielding layer 308 may be disposed surrounding the color filter layer 306. According to some embodiments, the light-shielding layer 308 may be located at the same level as the color filter layer 306, the light-shielding layer 308 may have multiple opening areas, and the color filter layer 306 may be filled in the opening areas. According to some embodiments, the upper surface of the light-shielding layer 308 may also be viewed as the starting position of display light. According to some embodiments, in the normal direction of the second substrate 200 (for example, the Z direction in the drawings), the light-shielding layer 308 may at least partially overlap the color filter layer 306. According to some embodiments, the light-shielding layer 308 may include a black matrix. The material of the light-shielding layer 308 may include black photoresist, black printing ink, black resin, metal, carbon black material, resin material, photosensitive material, other suitable materials, or a combination thereof, but the disclosure is not limited thereto.

According to some embodiments, the electronic device 10 includes a display unit layer DU, and the display unit layer DU includes multiple display units. In detail, according to some embodiments, the display unit layer DU may include an alignment layer 302A, a display medium layer 300, an alignment layer 302B, a color filter layer 306, and a light-shielding layer 308, and the range of one display unit is substantially the same as the range of one filter unit of the color filter layer 306. According to some embodiments, the display unit of the display unit layer DU is a unit that presents one viewing-angle screen, and may also be viewed as one pixel. The display unit layer DU has a function equivalent to a grating, and may be used to control switching or brightness of dual-view or multi-view screens.

In addition, the viewing-angle barrier layer 400 may contact one of the first surface 200a and the second surface 200b of the second substrate 200. In the embodiment as shown in FIG. 1, the viewing-angle barrier layer 400 contacts the first surface 200a of the second substrate 200. In other words, the viewing-angle barrier layer 400 and the display medium layer 300 are disposed on the same side (inner side) of the second substrate 200, and the viewing-angle barrier layer 400 may be viewed as embedded in the display unit (in-cell). The viewing-angle barrier layer 400 may have patterns corresponding to different opening angles for dual-view display or multi-view display. According to some embodiments, the viewing-angle barrier layer 400 may include multiple sub-barrier layers (not shown), and one of the sub-barrier layers contacts the second substrate 200. The viewing-angle barrier layer 400 may be formed by material having masking function. For example, according to some embodiments, the material of the viewing-angle barrier layer 400 may include black photoresist, black printing ink, black resin, metal, carbon black material, resin material, photosensitive material, other suitable materials, or a combination thereof, but the disclosure is not limited thereto. In addition, according to some embodiments, the patterned viewing-angle barrier layer 400 may be formed by one or more photolithography processes and/or etching processes. According to some embodiments, the photolithography process may include photoresist coating (for example, spin coating), soft baking, hard baking, mask alignment, exposure, post-exposure baking, photoresist development, cleaning and drying, etc., but the disclosure is not limited thereto. The etching process may include dry etching process or wet etching process, but the disclosure is not limited thereto.

Particularly, according to some embodiments, in the normal direction of the first surface 200a (for example, the Z direction in the drawing), a distance h between the viewing-angle barrier layer 400 and the color filter layer 306 may be between 37 μm and 518 μm (that is, 37 μm≤distance h≤518 μm), for example, 42 μm, 46 μm, 49 μm, 52 μm, 56 μm, 58 μm, 59 μm, 61 μm, 65 μm, 69 μm, 70 μm, 73 μm, 78 μm, 79 μm, 81 μm, 83 μm, 86 μm, 91 μm, 92 μm, 97 μm, 104 μm, 107 μm, 110 μm, 115 μm, 122 μm, 125 μm, 137 μm, 138 μm, 143 μm, 146 μm, 152 μm, 155 μm, 157 μm, 162 μm, 173 μm, 175 μm, 177 μm, 183 μm, 203 μm, 207 μm, 219 μm, 230 μm, 248 μm, 258 μm, 274 μm, 311 μm, 322 μm, 365 μm or 457 μm. This part of the content will be described in detail below. In detail, the distance h refers to the minimum distance between the viewing-angle barrier layer 400 and the color filter layer 306 in the normal direction of the first surface 200a (for example, the Z direction in the drawing).

According to some embodiments, the electronic device 10 may further include a planarization layer 402, and the planarization layer 402 may be disposed between the viewing-angle barrier layer 400 and the color filter layer 306. The planarization layer 402 may be used to adjust the distance from display light to the viewing-angle barrier layer 400 in the dual-view display design, and may provide a flat surface for forming the color filter layer 306 and the light-shielding layer 308. According to some embodiments, the refractive index of the planarization layer 402 may be between 1.2 and 1.7, for example, may be 1.3, 1.4, 1.5, or 1.6. The material of the planarization layer 402 may be an optically transparent material. The planarization layer 402 may include organic material or inorganic material. For example, according to some embodiments, the organic material may include perfluoroalkoxy alkane polymer (PFA), polytetrafluoroethylene (PTFE), fluorinated ethylene propylene (FEP), polyethylene, other suitable materials, or a combination thereof, but the disclosure is not limited thereto. According to some embodiments, the inorganic material may include silicon nitride, silicon oxide, silicon oxynitride, aluminum oxide, other suitable materials, or a combination thereof, but the disclosure is not limited thereto.

In addition, according to some embodiments, the electronic device 10 may further include an adhesive layer 310 and a polarizing layer 312, the adhesive layer 310 and the polarizing layer 312 may be disposed on the second surface 200b of the second substrate 200, and the adhesive layer 310 may be disposed between the second substrate 200 and the polarizing layer 312. The adhesive layer 310 may be used to fix the polarizing layer 312 on the second substrate 200, or may also have a planarization function. The adhesive layer 310 includes material having adhesiveness. According to some embodiments, the material of the adhesive layer 310 may include optical clear adhesive (OCA), optical clear resin (OCR), pressure sensitive adhesive (PSA), acrylic adhesive, acrylic resin, other suitable materials, or a combination thereof, but the disclosure is not limited thereto. Furthermore, according to some embodiments, the polarizing layer 312 may include poly vinyl alcohol (PVA) film. The polarizing layer 312 may have a single layer or multi-layer structure.

According to some embodiments, the electronic device 10 may further include a sensing element (not shown) disposed on the polarizing layer 312. The sensing element may be, for example, a touch layer, and the touch layer may include touch electrodes and conductive wires. According to some embodiments, the material of the touch electrodes and the material of the conductive wires may include metal material or transparent conductive material. For example, the metal material may include copper (Cu), aluminum (Al), indium (In), ruthenium (Ru), tin (Sn), gold (Au), platinum (Pt), zinc (Zn), silver (Ag), titanium (Ti), lead (Pb), nickel (Ni), chromium (Cr), magnesium (Mg), palladium (Pd), an alloy of the above materials, other suitable materials, or a combination thereof, but the disclosure is not limited thereto. The transparent conductive material may include, for example, indium tin oxide (ITO), tin oxide (SnO), zinc oxide (ZnO), indium zinc oxide (IZO), indium gallium zinc oxide (IGZO), indium tin oxide (ITZO), antimony tin oxide (ATO), antimony zinc oxide (AZO), other suitable transparent conductive materials, or a combination thereof, but the disclosure is not limited thereto.

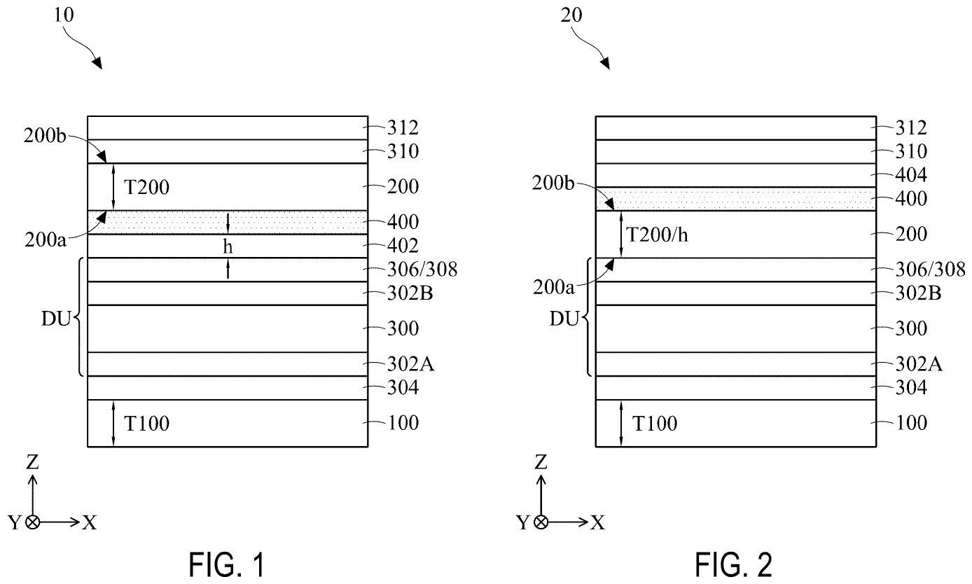

Next, referring to FIG. 2, FIG. 2 shows a schematic structural diagram of an electronic device 20 according to other embodiments of the disclosure. It should be noted that the drawing only schematically illustrates the stacked structure of the electronic device 20. According to some embodiments, additional features may be added to the electronic device 20 described below. According to some embodiments, the electronic device 20 may be an automotive display module, but the disclosure is not limited thereto.

The electronic device 20 shown in FIG. 2 is substantially similar to the electronic device 10. Compared with the electronic device 10, the viewing-angle barrier layer 400 in the electronic device 20 contacts the second surface 200b of the second substrate 200. In this embodiment, the viewing-angle barrier layer 400 and the display medium layer 300 are disposed on different sides of the second substrate 200 (the viewing-angle barrier layer 400 is disposed on the outer side), and the viewing-angle barrier layer 400 may be regarded as being located on the display unit (on-cell). In this embodiment, the refractive index of the second substrate 200 may be between 1.2 and 1.7, for example, may be 1.3, 1.4, 1.5, or 1.6.

In addition, as shown in FIG. 2, according to some embodiments, the electronic device 20 may further include a protection layer 404 disposed on the viewing-angle barrier layer 400, and the protection layer 404 may be disposed between the viewing-angle barrier layer 400 and the adhesive layer 310. The protection layer 404 may protect the viewing-angle barrier layer 400 disposed on the outer side of the second substrate 200, reducing the chance of the viewing-angle barrier layer 400 being damaged or harmed during the process. According to some embodiments, the material of the protection layer 404 may include silicon oxide, silicon nitride, silicon oxynitride, aluminum oxide, other suitable protective materials, or a combination thereof, but the disclosure is not limited thereto.

According to some embodiments, the electronic device 20 may also further include a sensing element (not shown) disposed on the polarizing layer 312. The sensing element may be, for example, a touch layer, and the touch layer may include touch electrodes and conductive wires.

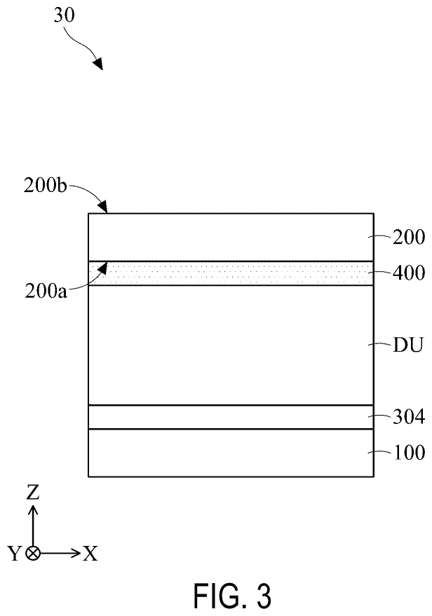

Furthermore, referring to FIG. 3, FIG. 3 shows a schematic structural diagram of an electronic device 30 according to other embodiments of the disclosure. It should be noted that the drawing only schematically illustrates the stacked structure of the electronic device 30. According to some embodiments, additional features may be added to the electronic device 30 described below. According to some embodiments, the electronic device 30 may be an automotive display module, but the disclosure is not limited thereto.

The electronic device 30 may include a first substrate 100, a second substrate 200, a driving circuit layer 304, a display unit layer DU, and a viewing-angle barrier layer 400. The driving circuit layer 304, the display unit layer DU, and the viewing-angle barrier layer 400 may be disposed between the first substrate 100 and the second substrate 200. The viewing-angle barrier layer 400 contacts the first surface 200a of the second substrate 200, and the display unit layer DU is disposed between the viewing-angle barrier layer 400 and the driving circuit layer 304. The display unit layer DU includes multiple display units. In this embodiment, the display units may be inorganic light-emitting diodes (LEDs), organic light-emitting diodes (OLEDs), or a combination thereof. In this embodiment, one display unit of the display unit layer DU is substantially the same as the pixel range of one inorganic light-emitting diode or organic light-emitting diode.

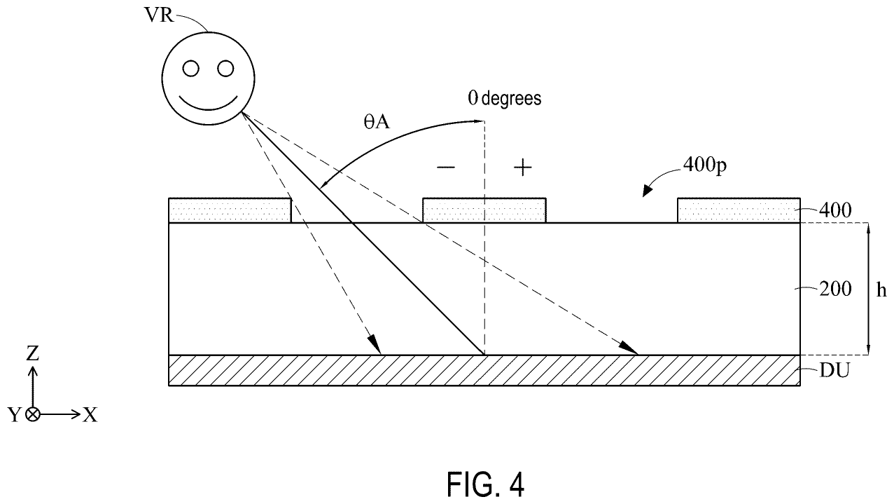

Next, the relationship between the light pattern diagram and the structure of the viewing-angle barrier layer 400 will be described. Referring to FIG. 4, FIG. 4 shows a schematic diagram of viewing-angle determination according to some embodiments of the disclosure. As shown in FIG. 4, the normal direction of the second substrate 200 may be defined as 0 degrees viewing-angle. When facing the electronic device (for example, on a side farther from the display unit layer DU), the left side of 0 degrees is a positive viewing-angle, and the right side of 0 degrees is a negative viewing-angle. For example, in the embodiment where the electronic device is as shown in FIG. 1, the viewing-angle barrier layer 400 is closer to a viewer VR than the second substrate 200. The viewer VR may view the image presented by the display unit layer DU through the opening 400p of the viewing-angle barrier layer 400 (which may be regarded as a transparent area). The viewing range of the viewer VR is angle θA, and the angle θA may be, for example, 30 degrees plus or minus 10 degrees. Furthermore, in automotive display modules, the typical configuration is that the panel is centered and the left and right passengers can have their respective viewing areas (for example, the viewing range of the left-hand drive position is at −30 degrees±10 degrees, and the viewing range of the right-hand drive position is at +30 degrees±10 degrees), and the respective viewing areas do not interfere with each other.

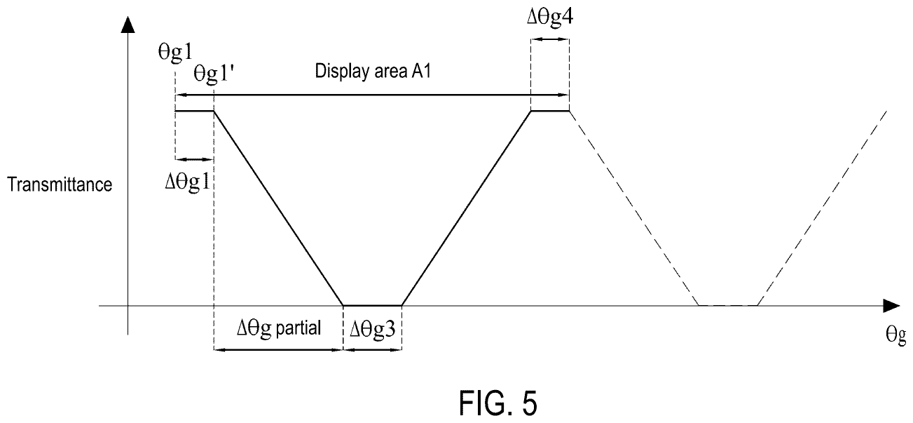

Based on the above, the schematic diagram of the geometric relationship as shown in FIG. 4 may be derived from the opening 400p (transparent area) of the viewing-angle barrier layer 400, the display unit layer DU, and the distance h between the viewing-angle barrier layer 400 and the color filter layer 306. Referring to FIG. 5, FIG. 5 shows a light pattern distribution diagram illustrating the relationship between transmittance (opening ratio) and viewing-angle (θg) inferred from the geometric relationship. As shown in FIG. 5, Δθg1 and Δθg4 are angle ranges from which the complete display area A1 of the display unit layer DU can be viewed, Δθg3 is an angle range from which the display area A1 cannot be viewed, and the areas between Δθg1 to Δθg3 and between Δθg3 to Δθg4 are angle ranges from which partial display area A1 can be viewed. Moreover, the angle ranges of the Δθg display area A1 and the Δθg partial may be obtained therefrom, where Δθg display area A1 refers to the entire angle range from which the display area A1 can be viewed, and Δθg partial refers to the angle range from which the light-emitting gradient area can be viewed.

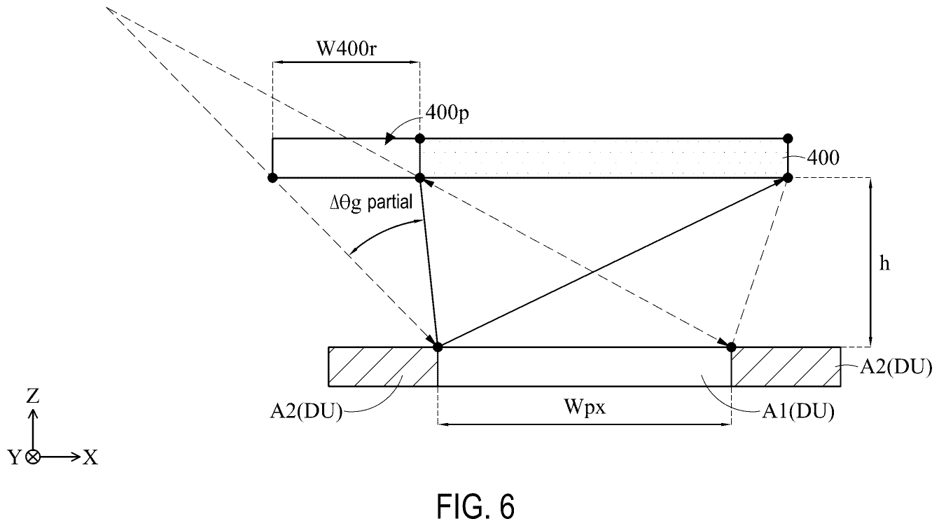

Based on the above, a light pattern diagram may be derived from the schematic diagram of the geometric relationship, and conversely, the geometric relationship between the viewing-angle barrier layer 400 and the display area A1 may also be designed according to the light pattern diagram. Moreover, as long as the design is performed for one viewing-angle, other viewing-angles will satisfy translational symmetry and thus may be reused. Referring to FIG. 6, FIG. 6 shows a schematic structural diagram of some components of an electronic device including design parameters according to some embodiments of the disclosure. The schematic diagram of the geometric relationship as shown in FIG. 6 may be derived from the opening 400p (transparent area) of the viewing-angle barrier layer 400, the display area A1 and non-display area A2 of the display unit layer DU, and the distance h between the viewing-angle barrier layer 400 and the display unit layer DU. The opening 400p (transparent area) of the viewing-angle barrier layer 400 may have a width of W400r. The display area A1 of the display unit layer DU may have a width of Wpx. The angle range of Δθg partial may be derived from the positional relationship between the opening 400p of the viewing-angle barrier layer 400 and the display area A1 of the display unit layer DU.

It should be understood that in the embodiment shown in FIG. 6, the transparent area of the viewing-angle barrier layer 400 may be less than the display area A1 of the display unit layer DU, but the disclosure is not limited thereto. According to some other embodiments, the transparent area of the viewing-angle barrier layer 400 may be greater than the display area A1 of the display unit layer DU. In addition, FIG. 6 illustrates the structure of the electronic device 10 as shown in FIG. 1 as an example, and therefore the distance h may be the height of the planarization layer 402. In terms of the structure of the electronic device 20 as shown in FIG. 2, the distance h is the height of the thinned second substrate 200.

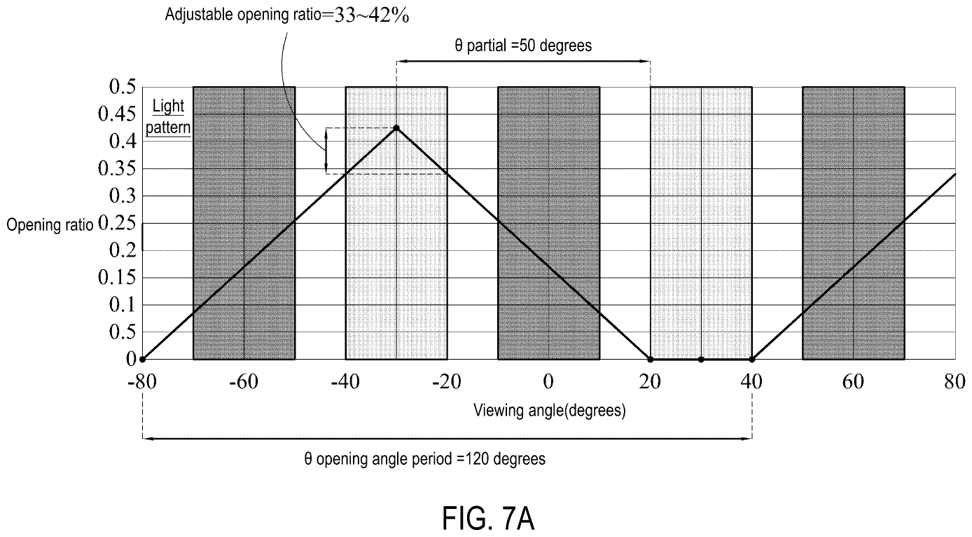

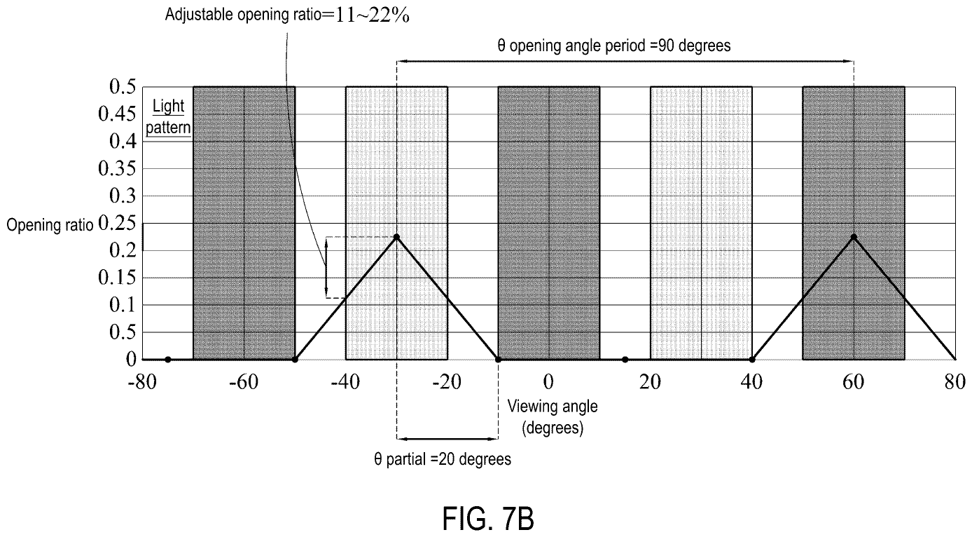

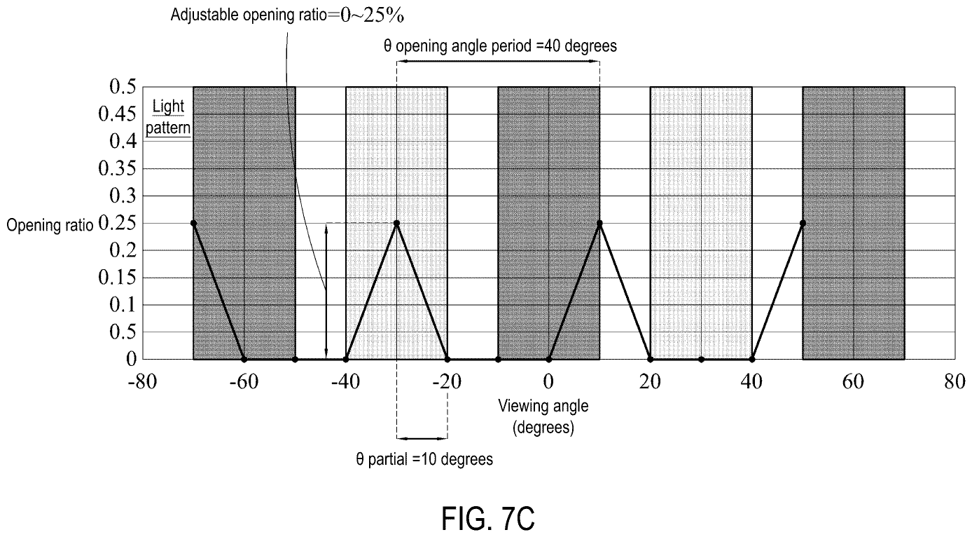

Referring to FIG. 7A to FIG. 7C, FIG. 7A to FIG. 7C show different types of light pattern diagrams (in terms of left-hand drive viewing-angle) according to some embodiments of the disclosure. Specifically, the light patterns may be divided into three categories as shown in FIG. 7A to FIG. 7C according to the required opening angle (period) in air.

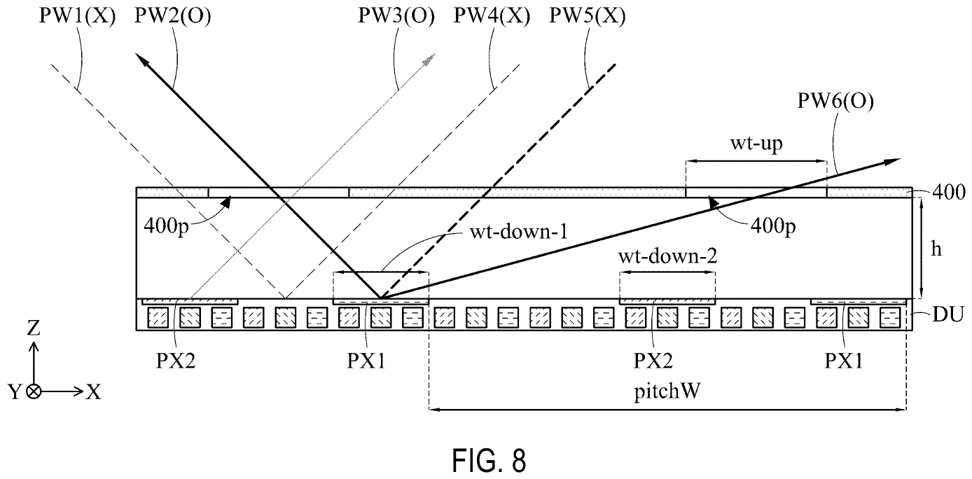

As the requirements for left and right viewing-angles differ (θR±ΔθR, θL±ΔθL), the opening angle period may vary, and the main reasons for this classification are described as follows. In FIG. 7A, the starting point of the left viewing dark area angle is positioned between θR+ΔθR and θL−ΔθL, and the ending point of the left viewing dark area angle is greater than θL+ΔθL. Since a smaller period under the same height h may have larger dual-view pixels per inch (DVppi), the minimum opening angle period in this scenario is 2*(θL−θR). The dual-view pixel includes a first viewing-angle pixel and a second viewing-angle pixel. For detailed content regarding dual-view pixels, reference may be made to the description of FIG. 8. In FIG. 7B, aside from the angle requirements for the left-hand drive and the right-hand drive, if it is also necessary to ensure that the passenger in the rear middle seat does not see the images from both the left-hand drive side and the right-hand drive side within a specific angle range (+θc±Δθc), then the starting point of the left viewing dark area angle is positioned between θR+ΔθR and θC−ΔθC (in this example, θC−Δθ is selected as the starting point of the left viewing dark area angle to provide a higher intensity of the bright area platform for the left-hand drive), and the ending point of the left viewing dark area angle is greater than θL+ΔθL. Since a smaller period under the same distance h may have larger DVppi, the minimum opening angle period in this scenario is (θL+ΔθL)−θR+(θC−ΔθC−θR)=θL+θC−2θR+(ΔθL−ΔθC). In FIG. 7C, it is desired to obtain a smaller opening angle period (θT), and therefore 2θT=(θL+ΔθL)−(θR−ΔθR). In addition, the left-hand drive position image cannot interfere with the right-hand drive image, so the starting point of the left viewing dark area angle is positioned at θR+ΔθR, and the ending point of the left viewing dark area angle is positioned at θR+ΔθR+2*ΔθL. Similarly, the right-hand drive may also satisfy a similar relational expression.

In addition, as shown in FIG. 7A, the corresponding θ opening angle period is 120 degrees, mainly applied in scenarios where the left-hand drive viewing range is at −30 degrees±10 degrees, the right-hand drive viewing range is at 30 degrees±10 degrees, and mutual interference is not allowed in their respective viewing areas. As shown in FIG. 7B, the corresponding θ opening angle period is 90 degrees, mainly applied in scenarios where the left-hand drive viewing range is at −30 degrees±10 degrees, the right-hand drive viewing range is at 30 degrees±10 degrees, and mutual interference is not allowed in their respective viewing areas. In addition, the range where mixed images are not visible at the rear middle position is at 0 degrees±10 degrees. As shown in FIG. 7C, the corresponding θ opening angle period is 40 degrees, mainly applied in scenarios where the left-hand drive viewing range is at −30 degrees±10 degrees, the right-hand drive viewing range is at 30 degrees±10 degrees, and mutual interference is not allowed in their respective viewing areas.

The opening angle period may be further adjusted according to the upper and lower boundaries of specification requirements. Once the opening angle of the light pattern is determined, the opening ratio is confirmed: opening ratio=gradient area angle/opening angle period=θpartial/θ opening angle period (θpitch), where θpartial=angle difference between the center and edge of the viewing area. For example, in FIG. 7A, (20 degrees−(−30 degrees))/120 degrees=50/120=42%, (20 degrees−(−20 degrees))/120 degrees=40/120=33%. After designing the geometric structure and corresponding light pattern, if it is desired that the light intensity of the left viewing-angle (−30 degrees±10 degrees) does not vary with angle (fixed opening ratio), this may be achieved by changing the geometric structure (refer to FIG. 8, keeping wt_down+wt_up fixed in the diagram, and reducing the dimension of the smaller one between wt_down and wt_up) to obtain a similar light pattern with a fixed bright area platform. In other words, the light intensity of the bright area platform is determined by the smaller wt_min/θpitch, but the disclosure is not limited thereto.

Referring to FIG. 8, FIG. 8 shows a schematic structural diagram of some components of an electronic device including design parameters according to some embodiments of the disclosure. The schematic diagram of the geometric relationship as shown in FIG. 8 may be derived from the opening 400p of the viewing-angle barrier layer 400 (transparent area having a width of wt-up), the display unit layer DU, and the distance h between the viewing-angle barrier layer 400 and the display unit layer DU. The paths of light ray PW1, light ray PW4, and light ray PW5 do not pass through the opening 400p of the viewing-angle barrier layer 400, and are therefore not visible to the viewer (marked with X). The paths of light ray PW2, light ray PW3, and light ray PW6 pass through the opening 400p of the viewing-angle barrier layer 400, and are therefore visible to the viewer (marked with O).

In detail, the opening 400p of the viewing-angle barrier layer 400 is a transparent area having a width of wt-up, where the width of wt-up refers to the maximum width of the opening 400p of the viewing-angle barrier layer 400 in a direction perpendicular to the normal direction of the viewing-angle barrier layer 400 (for example, the X direction in the diagram). Furthermore, according to some embodiments, the electronic device may serve as a dual-view display, and the display unit layer DU has a first viewing-angle pixel PX1 and a second viewing-angle pixel PX2. Multiple first viewing-angle pixels PX1 present a first viewing-angle image, and the first viewing-angle image may be presented to a first viewing-angle observer (for example, left-hand drive). In other words, the display light of the first viewing-angle pixels PX1 transmits through the viewing-angle barrier layer 400 to enable the first viewing-angle observer to view the first viewing-angle image. Multiple second viewing-angle pixels PX2 present a second viewing-angle image, and the second viewing-angle image may be presented to a second viewing-angle observer (for example, right-hand drive driver/passenger). In other words, the display light of the second viewing-angle pixels PX2 transmits through the viewing-angle barrier layer 400 to enable the second viewing-angle observer to view the second viewing-angle image. In addition, the first viewing-angle pixel PX1 has a width of wt-down-1, and the second viewing-angle pixel PX2 has a width of wt-down-2. Moreover, adjacent first viewing-angle pixels PX1 may have a pitch of pitchW, and adjacent second viewing-angle pixels PX2 may have a pitch of pitchW.

Referring to Table 1, Table 1 shows the optimal range of opening ratio that may be adjusted within a center angle of ±10 degrees for the corresponding bright area platform under specific light patterns (different required opening angles (periods) in the air). (A smaller angle range of the bright area platform corresponds to a higher opening ratio).

TABLE 1

| opening ratio (limit) | viewable or not | opening angle |
|---|---|---|
| bright area platform | in the middle | θp in air period |
| 33%-42% | Yes | 120 |
| 11%-22% | No | 90 |
| 0%-25% | Yes | 40 |

In addition, to obtain the limit value of Dvppi in the design, it is necessary to first know the following parameters: the distance h between the display unit layer DU and the viewing-angle barrier layer 400 (for example, in some embodiments, the distance from the upper surface of the color filter layer 306 to the lower surface of the viewing-angle barrier layer 400), and the refractive index of the material between the display unit layer DU and the viewing-angle barrier layer 400, as well as the distance h (in units of μm). If the refractive index of the medium is ng, the required period width of the viewing-angle barrier layer 400 (corresponding to the width of the pitchW) may be calculated from DVppi. If the corresponding light pattern period angle in the design is θp(θpitch), then the calculation is performed using the following formula:

$$pitchW = 25400 / Dvppi ( 1 inch = 2.54 \times 10 \hat{} - 2 m = 2.54 \times 10 \hat{} 4 μm )$$

$$A ≡ 2 * tan ( asin ( sin ( π / 18 ) / ng ) / 2 ( π = 3.1415 … )$$

$$h = 10 * pitchW / ( θ p * A ) = 254000 / ( DVppi * θ p * A )$$

Referring to Tables 2 to 4 below, Tables 2 to 4 show the maximum height limitations corresponding to different light patterns under different media (ng).

Table 2 shows the opening ratio limit under different design scenarios for left and right viewing when n=1.5, h˜2191626/(DVppi*θρ) (independent of DVppi).

| | | | h | | | | | | | |
|---|---|---|---|---|---|---|---|---|---|---|
| opening ratio | viewable | opening | fixed | hmax | hmax | hmax | hmax | hmax | hmax | hmax |
| (limit) @bright | or not | angle θp | DV | [μm] | [μm] | [μm] | [μm] | [μm] | [μm] | [μm] |
| area platform | in the | in air | ppi | @400 | @350 | @300 | @250 | @200 | @170 | @120 |
| (≤±10°) | middle | (period) | ratio | DVppi | DVppi | DVppi | DVppi | DVppi | DVppi | DVppi |
| 33%~42% | yes | 120 | 1 | 46 | 52 | 61 | 73 | 91 | 107 | 152 |
| 11%~22% | no | 90 | 1.33 | 61 | 70 | 81 | 97 | 122 | 143 | 203 |
| 0%~25% | yes | 40 | 3 | 137 | 157 | 183 | 219 | 274 | 322 | 457 |

Angle center: left view (−30 degrees), right view (+30 degrees), rear view (0 degrees)

Table 3 shows the opening ratio limit under different design scenarios for left and right viewing when n=1.2, h˜1752180/(DVppi*θρ) (independent of DVppi).

| | | | h | | | | | | | |
|---|---|---|---|---|---|---|---|---|---|---|
| opening ratio | viewable | opening | fixed | hmax | hmax | hmax | hmax | hmax | hmax | hmax |
| (limit) @bright | or not | angle θp | DV | [um] | [um] | [um] | [um] | [um] | [um] | [um] |
| area platform | in the | in air | ppi | @400 | @350 | @300 | @250 | @200 | @170 | @120 |
| (≤±10°) | middle | (period) | ratio | DVppi | DVppi | DVppi | DVppi | DVppi | DVppi | DVppi |
| 33%~42% | yes | 120 | 1 | 37 | 42 | 49 | 58 | 73 | 86 | 122 |
| 11%~22% | no | 90 | 1.33 | 49 | 56 | 65 | 78 | 97 | 115 | 162 |
| 0%~25% | yes | 40 | 3 | 110 | 125 | 146 | 175 | 219 | 258 | 365 |

Angle center: left view (−30 degrees), right view (+30 degrees), rear view (0 degrees)

Table 4 shows the opening ratio limit under different design scenarios for left and right viewing when n=1.7, h˜2484464/(DVppi*θρ) (independent of DVppi).

| | | | h | | | | | | | |
|---|---|---|---|---|---|---|---|---|---|---|
| opening ratio | viewable | opening | fixed | hmax | hmax | hmax | hmax | hmax | hmax | hmax |
| (limit) @bright | or not | angle θp | DV | [um] | [um] | [um] | [um] | [um] | [um] | [um] |
| area platform | in the | in air | ppi | @400 | @350 | @300 | @250 | @200 | @170 | @120 |
| (≤±10°) | middle | (period) | ratio | DVppi | DVppi | DVppi | DVppi | DVppi | DVppi | DVppi |
| 33%~42% | yes | 120 | 1 | 52 | 59 | 69 | 83 | 104 | 122 | 173 |
| 11%~22% | no | 90 | 1.33 | 69 | 79 | 92 | 110 | 138 | 162 | 230 |
| 0%~25% | yes | 40 | 3 | 155 | 177 | 207 | 248 | 311 | 365 | 518 |

Angle center: left view (−30 degrees), right view (+30 degrees), rear view (0 degrees)

From the above, it is known that when the dual-view resolution needs to reach 170 ppi, the distance h needs to be less than a certain value. For example, when ng=1.5 and there is no visible mixed image in the middle, and the opening angle is 90 degrees, the distance h needs to be less than 143 μm to achieve the desired outcome. It may be found from the table that a smaller opening angle period allows for a larger design value for distance h, but it should be noted that it still needs to be combined with the structure design of the display unit layer DU. As mentioned above, in some embodiments, when the electronic device adopts a non-self-luminous type display, the integration of the viewing-angle barrier layer 400 technology within the color filter substrate (in-cell) may effectively reduce the distance h, thereby improving the dual-view resolution.

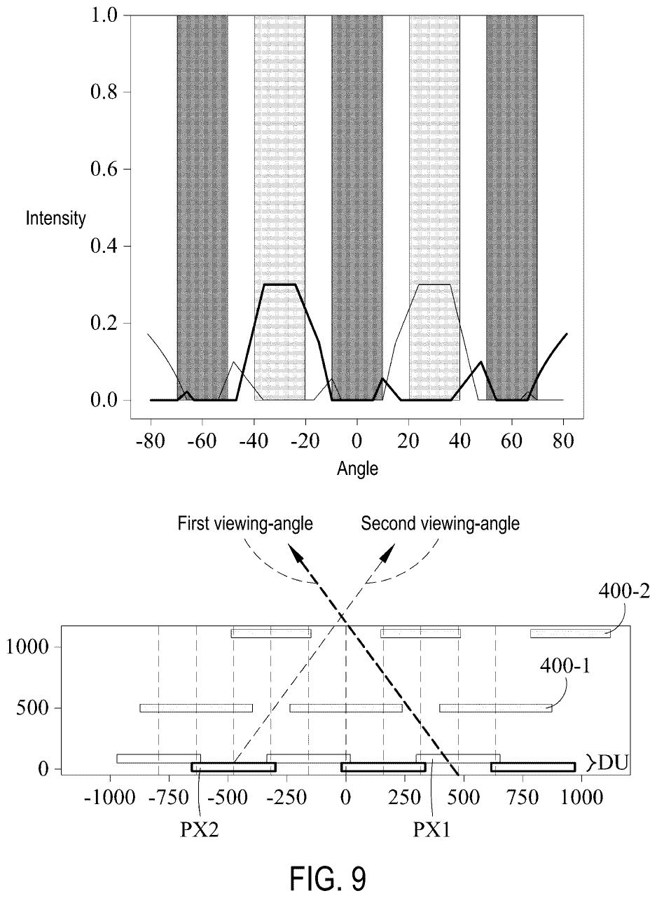

In addition, referring to FIG. 9, FIG. 9 shows corresponding light pattern diagrams obtained by using different viewing-angle barrier layers 400 according to some embodiments of the disclosure. The dark-colored columns in the upper diagram represent light rays presented to a first viewing-angle observer (for example, a left-hand drive driver), and the light-colored columns represent light rays presented to a second viewing-angle observer (for example, a right-hand drive driver). As shown in FIG. 9, according to some embodiments, two or more viewing-angle barrier layers 400 (for example, viewing-angle barrier layer 400-1 and viewing-angle barrier layer 400-2 in the diagram) may be used to achieve the opening angle of the required scenario to increase design flexibility. When designing two viewing-angle barrier layers 400, the light layer may be divided into two layers (viewing-angle barrier layer 400-1 and viewing-angle barrier layer 400-2) and each may be individually designed according to requirements. In other words, when designing multiple viewing-angle barrier layers 400, the distance h between the display unit layer DU and the corresponding layer of the viewing-angle barrier layer 400 may be independently calculated by applying the formula, and the final combined light pattern is the result of multiplying the two in sequence. According to some embodiments, the width of the viewing-angle barrier layer 400-2 may be less than the width of the viewing-angle barrier layer 400-1, and the opening of the viewing-angle barrier layer 400-2 and the opening of the viewing-angle barrier layer 400-1 overlap. In particular, the configuration of multiple viewing-angle barrier layers 400 may further reduce light leakage and improve the quality of the display screen. Furthermore, according to some embodiments, the size of the lower viewing-angle barrier layer 400-1 may be adjusted to be an integer multiple of the display area A1 (not shown) of the display unit layer DU, so that the lower viewing-angle barrier layer 400-1 may be omitted and replaced by using switches of the display unit layer DU for control.

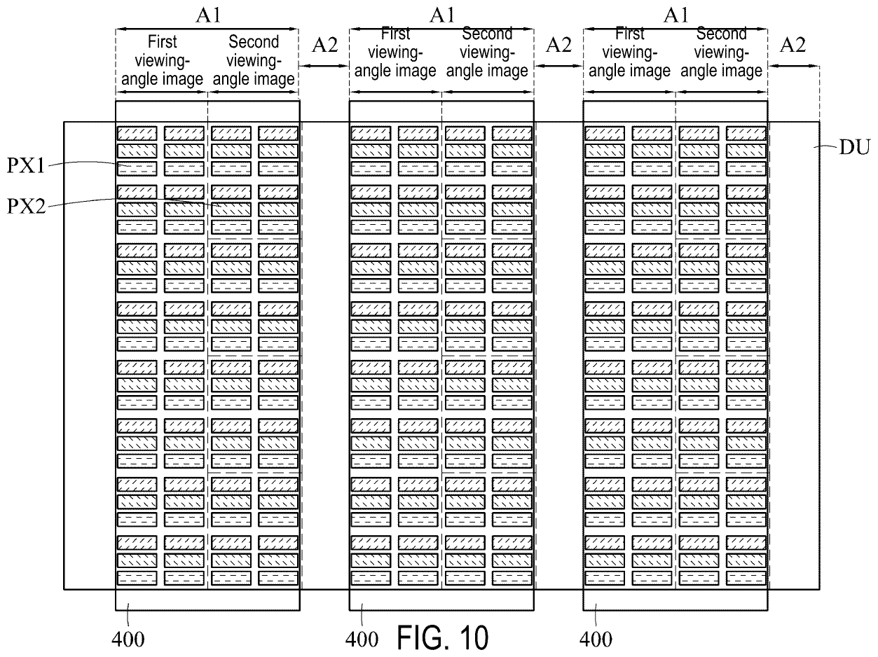

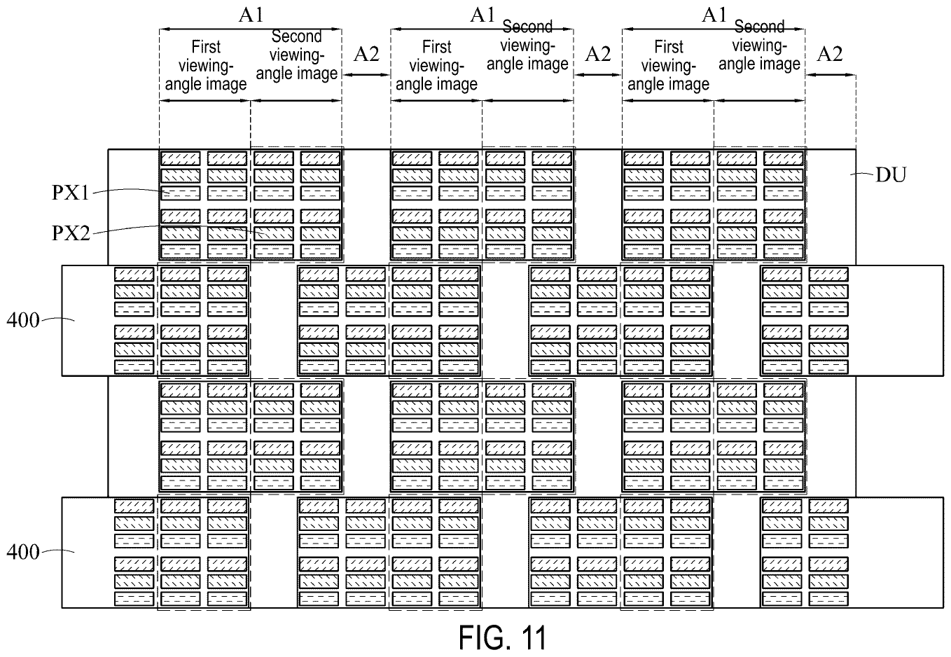

Next, referring to FIG. 10 and FIG. 11, FIG. 10 and FIG. 11 show schematic structural diagrams of some components in an electronic device according to some embodiments of the disclosure. Specifically, FIG. 10 and FIG. 11 illustrate the configuration relationship between the viewing-angle barrier layer 400 and the first viewing-angle pixel PX and the second viewing-angle pixel PX2 in the display unit layer DU in the electronic device. The display unit layer DU includes a display area A1 and a non-display area A2. The second viewing-angle pixel PX2 controlling the second viewing-angle image is marked with a dashed frame. As shown in FIG. 10, according to some embodiments, the long side direction of the viewing-angle barrier layer 400 (for example, stripe grating) may be arranged perpendicular to the first viewing-angle pixel PX or the second viewing-angle pixel PX2 (for example, sub-pixel), thereby reducing the phenomenon of uneven color in the display screen. In addition, in embodiments where the long side direction of the viewing-angle barrier layer 400 is arranged perpendicular to the first viewing-angle pixel PX or the second viewing-angle pixel PX2, a viewing-angle barrier layer 400 with a period width that is the same as or an integer multiple of the pitch width (width corresponding to pitchW) may be selected to reduce the generation of moiré patterns, and this method has no effect on resolution.

Furthermore, as shown in FIG. 11, according to some embodiments, the viewing-angle barrier layer 400 may be arranged in a staggered manner, for example, arranged in a checkerboard pattern distribution. Such a configuration may further reduce the screen streaks perceived by the viewers (for example, reduce moiré patterns). In addition, according to some embodiments, the viewing-angle barrier layer 400 (for example, stripe grating) may also be obliquely attached so that there is an angle between the long side direction of the viewing-angle barrier layer 400 and the long side of the first viewing-angle pixel PX or the second viewing-angle pixel PX2. Such a method may reduce moiré patterns, but attention needs to be paid to the proportion of left viewing and right viewing-angles. On the other hand, the non-display area A2 of the display unit layer DU may also be used as a white screen to increase screen brightness, but the contrast will be relatively reduced.

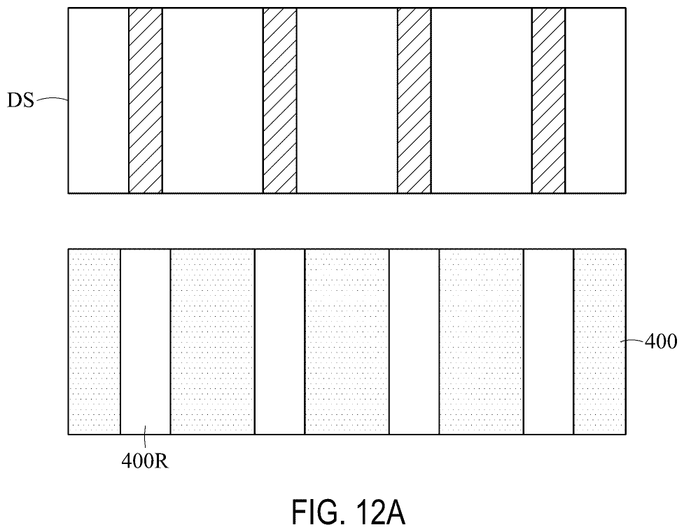

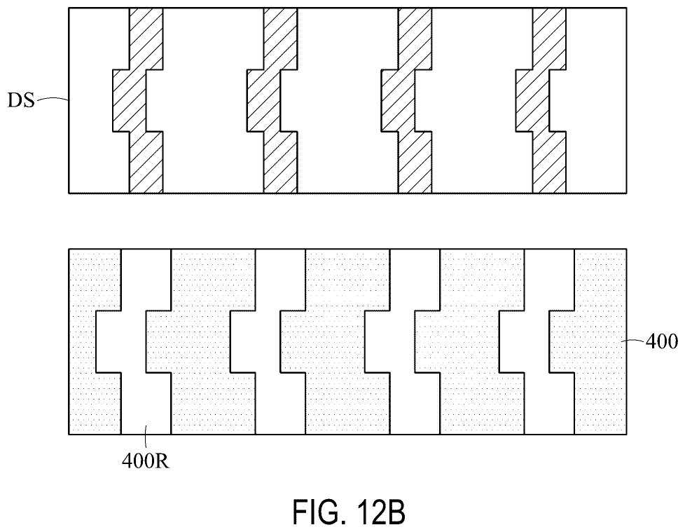

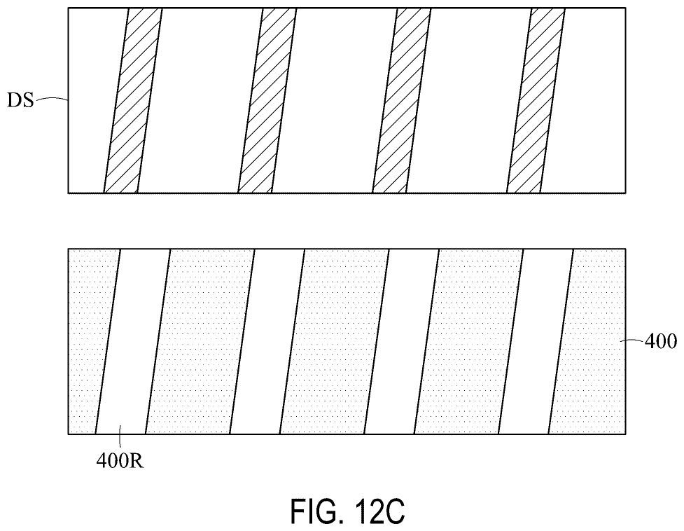

Referring to FIG. 12A to FIG. 12C, FIG. 12A to FIG. 12C show top view schematic structural diagrams of viewing-angle barrier layers 400 of different aspects and schematic diagrams of the displayed screens DS according to some embodiments of the disclosure. As shown in FIG. 12A to FIG. 12C, the viewing-angle barrier layer 400 may include multiple transparent areas 400R, and these transparent areas 400R may be arranged in a staggered manner. As shown in FIG. 12A, according to some embodiments, the viewing-angle barrier layer 400 may have a stripe grating structure, the extension direction of the stripes may be substantially parallel to the short side direction of the viewing-angle barrier layer 400, and the displayed screen DS includes patterns corresponding to the transparent areas 400R. As shown in FIG. 12B, according to some embodiments, the viewing-angle barrier layer 400 may have a pattern grating structure, the patterns include, for example, multiple concave portions and convex portions, and the displayed screen DS includes patterns corresponding to the transparent areas 400R. As shown in FIG. 12C, according to some embodiments, the viewing-angle barrier layer 400 may have an oblique stripe grating structure, the extension direction of the oblique stripes is neither parallel to the short side direction nor the long side direction of the viewing-angle barrier layer 400, and the displayed screen DS includes patterns corresponding to the transparent areas 400R.

In summary, according to embodiments of the disclosure, an electronic device including a viewing-angle barrier layer is provided. The viewing-angle barrier layer may be disposed within the color filter substrate (in-cell) or on the thinned color filter substrate (on-cell), and is manufactured by a photolithography process, thereby improving the alignment accuracy of the viewing-angle barrier layer, and further improving the process yield and performance of the electronic device.

Although the embodiments of the disclosure and the advantages of the embodiments have been disclosed above, it should be understood that any person of ordinary skill in the art may make changes, substitutions, and modifications without departing from the spirit and scope of the disclosure. Moreover, the features of the various embodiments may be mixed and replaced with each other at discretion to form other new embodiments. In addition, the protection scope of the disclosure is not limited to the processes, machines, manufacture, compositions of matter, devices, methods, and steps in the specific embodiments described in the specification. Any person of ordinary skill in the art may understand the present or future developed processes, machines, manufacture, compositions of matter, devices, methods, and steps from the disclosure, which may be used based on the disclosure as long as they can perform substantially the same functions or achieve substantially the same results in the embodiments described herein. Therefore, the protection scope of the disclosure includes the above-mentioned processes, machines, manufacture, compositions of matter, devices, methods, and steps. In addition, each claim constitutes a separate embodiment, and the protection scope of the disclosure also includes combinations of each claim and the embodiment. The scope of protection of the disclosure shall be defined by the appended claims.

What is claimed is:

1. An electronic device, comprising:
a first substrate;
a second substrate, disposed opposite to the first substrate, and comprising a first surface facing the first substrate and a second surface facing away from the first substrate;
a display medium layer, disposed between the first substrate and the second substrate;
a color filter layer, disposed between the display medium layer and the second substrate; and
a viewing-angle barrier layer, contacting one of the first surface and the second surface,
wherein in a normal direction of the first surface, a thickness of the second substrate is less than a thickness of the first substrate.

2. The electronic device according to claim 1, wherein in the normal direction of the first surface, a distance between the viewing-angle barrier layer and the color filter layer is between 37 micrometers and 518 micrometers.

3. The electronic device according to claim 1, wherein the viewing-angle barrier layer contacts the first surface.

4. The electronic device according to claim 3, further comprising:
a planarization layer, disposed between the viewing-angle barrier layer and the color filter layer.

5. The electronic device according to claim 4, wherein a refractive index of the planarization layer is between 1.2 and 1.7.

6. The electronic device according to claim 4, wherein a distance between the viewing-angle barrier layer and the color filter layer is a height of the planarization layer.

7. The electronic device according to claim 3, wherein the viewing-angle barrier layer and the display medium layer are disposed on a same side of the second substrate.

8. The electronic device according to claim 1, wherein the viewing-angle barrier layer contacts the second surface.

9. The electronic device according to claim 8, wherein a refractive index of the second substrate is between 1.2 and 1.7.

10. The electronic device according to claim 8, wherein a distance between the viewing-angle barrier layer and the color filter layer is a height of the second substrate.

11. The electronic device according to claim 8, wherein the viewing-angle barrier layer and the display medium layer are disposed on different sides of the second substrate.

12. The electronic device according to claim 8, further comprising:
a protection layer, wherein the viewing-angle barrier layer is disposed between the protection layer and the second substrate.

13. The electronic device according to claim 1, wherein the display medium layer comprises a liquid crystal, an organic light-emitting diode (OLED), or a micro light-emitting diode (micro LED).

14. The electronic device according to claim 1, wherein the viewing-angle barrier layer comprises a plurality of sub-barrier layers.

15. The electronic device according to claim 1, wherein the viewing-angle barrier layer comprises a plurality of transparent areas, and the transparent areas are arranged in a staggered manner.

16. The electronic device according to claim 1, wherein the viewing-angle barrier layer is formed by a material having a masking function.

17. The electronic device according to claim 1, further comprising:
a polarizing layer, disposed on the second surface of the second substrate.

18. The electronic device according to claim 1, further comprising:
a display unit layer, comprising the display medium layer and the color filter layer, and having a display area and a non-display area,
wherein a width of a transparent area of the viewing-angle barrier layer is less than a width of the display area.

19. The electronic device according to claim 1, wherein the viewing-angle barrier layer comprises a first viewing-angle barrier layer and a second viewing-angle barrier layer, the first viewing-angle barrier layer is disposed between the second viewing-angle barrier layer and the display medium layer, and a width of the second viewing-angle barrier layer is less than a width of the first viewing-angle barrier layer.

20. The electronic device according to claim 19, wherein an opening of the first viewing-angle barrier layer does not overlap an opening of the second viewing-angle barrier layer.
